(19) United States
(12) Patent Application Publication
(10) Pub. No.: US 2013/0113498 A1
(43) Pub. Date: May 9, 2013

(54) TEST DEVICE WITH UNINTERRUPTIBLE POWER SUPPLY

(71) Applicants: CHENG-TE LIU, NEW TAIPEI CITY (TW); CHING-FENG HSIEH, TAIPEI CITY (TW)

(72) Inventors: CHENG-TE LIU, NEW TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/336,061

(22) Filed: Dec. 23, 2011

(30) Foreign Application Priority Data
Nov. 8, 2011 (TW) 100140780

(51) Int. Cl. G01R 31/00

(52) U.S. Cl. 324/555

(57) ABSTRACT

A test device with uninterruptible power supply supplies external power to a product under test (PUT) and performing electric power tests thereon. The PUT has a processing unit, a power input end, a battery connection end, and a charging and discharging circuit. The device includes a first test port, a second test port, and a power-storing unit. The PUT is electrically connected to the first and second test ports to receive the external power through the first test port and be switchable to the second test port to selectively receive power from the power-storing unit, thereby preventing interruption of operation of the PUT. A charging voltage from the charging and discharging circuit is applied to the power-storing unit via the second test port to charge the power-storing unit. An operation-required power level of the PUT can be maintained, even if the test device receives no power.

### CROSS-REFERENCE TO RELATED APPLICATION

This non-provisional application claims priority under 35 U.S.C. §119(a) on Patent Application No(s). 100140780 filed in Taiwan, R.O.C. on Nov. 8, 2011, the entire contents of which are hereby incorporated by reference.

### FIELD OF TECHNOLOGY

The present invention relates to test devices with uninterruptible power supply, and more particularly, to a test device that reduces the time taken to perform a test on a product under test (PUT) by providing uninterruptible power supply to the PUT during the test and maintaining the operation of the PUT.

### BACKGROUND

According to the prior art, testing production lines perform multiple battery status tests, such as a power consumption test, a software test, or a system stability test, on a product under test (PUT), such as a portable mobile device, a tablet computer, or any electronic product that requires power supply.

In general, the tests are performed at different testing production lines, respectively, and the testing production lines are separated by a distance, thereby preventing the PUT from having instant access to utility power supply. Furthermore, the PUT can operate only after its built-in operating system is started. Persons skilled in the art fully understand the following: it takes time to boot the PUT regardless of the type of the operation system installed thereon; switching the PUT between testing production lines requires an intricate operation procedure, including shutting down the PUT and starting the PUT; and, for the aforesaid two reasons, the tests performed on the PUT at different testing production lines are time-consuming.

That is to say, the booting of the PUT installed with the operating system necessarily takes time, and the switching of the PUT from one testing production line to the other testing production line in order to undergo a test requires shutting down the operating system of the PUT first and then restarting the operating system of the PUT at the other testing production line before the test begins, thereby causing a waste of time.

In view of the aforesaid drawbacks of the prior art, the present invention proposes a test device with uninterruptible power supply for overcoming the aforesaid drawbacks of the prior art, so as to ensure that the PUT is always maintained at an ON state during a test performed by the testing production lines.

### SUMMARY

It is an objective of the present invention to provide a test device with uninterruptible power supply that reduces the time taken to perform a test on a product under test (PUT) by providing uninterruptible power supply to the PUT during the test and maintaining the operation of the PUT.

Another objective of the present invention is to provide the test device with uninterruptible power supply so as to achieve a testing environment characterized by uninterruptible power supply, using selectively an external power or an electric power stored in a power-storing unit built in the test device with uninterruptible power supply.

Yet another objective of the present invention is to provide the test device with uninterruptible power supply, wherein a charging and discharging circuit in the PUT charges the power-storing unit, thereby dispensing with the hassles of providing a charging and discharging circuit in the test device with uninterruptible power supply.

A further objective of the present invention is to provide the test device with uninterruptible power supply for maintaining the operation of the PUT by switching a control circuit, including selecting between performing an electric power consumption test by a simulation battery or supplying an electric power from the power-storing unit.

A further objective of the present invention is to provide the test device with uninterruptible power supply for compensating for power supply suspension that occurs while the control circuit is switching between the power-storing unit and the simulation battery, so as to maintain the operation of the PUT during the switching process.

In order to achieve the above and other objectives, the present invention provides a test device with uninterruptible power supply, supplying an external power to a product under test (PUT), the PUT comprising a processing unit, a power input end, a battery connection end, and a charging and discharging circuit, the charging and discharging circuit receiving the external power via the power input end, being connected to the battery connection end, and being controlled by the processing unit, the test device comprising: a test platform having a first test port connected to the power input end and a second test port connected to the battery connection end; a first electrical connection unit connected to the first test port and receiving the external power, the external power being transmitted to the PUT via the first test port; a second electrical connection unit having a first charging and discharging connection end and a second charging and discharging connection end, the first charging and discharging connection end being connected to the battery connection end via the second test port; and a power-storing unit having a power-storing space stored therein with a battery power, connected to the second test port via the second charging and discharging connection end, and performing two-way charging and discharging, the battery power being supplied to the battery connection end, and the power-storing space receiving a charging voltage generated by the charging and discharging circuit.

In order to achieve the above and other objectives, the present invention provides a test device with uninterruptible power supply. In addition to the test platform, the first electrical connection unit, the second electrical connection unit, and the power-storing unit in the preceding embodiment, the test device with uninterruptible power supply further comprises a control unit. The control unit has a first connection port, a second connection port, and a third connection port. The control unit is disposed between the second charging and discharging connection end and the power-storing unit. The first connection port is switchable between the second connection port and the third connection port. The second connection port is connected to the power-storing unit.

As disclosed in the present invention, a test device with uninterruptible power supply not only enables the PUT to receive the external power EPW required for the operation of the PUT, but also enables the PUT to selectively allow the power-storing unit built in the test device with uninterruptible power supply to supply the power required for the operation of the PUT. Hence, the present invention ensures that the PUT can maintain its operation while being switched between testing production lines and receiving no external power EPW which should otherwise be supplied to the PUT, such that the PUT can be freely switched between the testing production lines without restarting.

Furthermore, the present invention dispenses with the hassles of providing a charging and discharging circuit for charging the power-storing unit, because the present invention discloses that the charging and discharging circuit of the PUT charges the power-storing unit.

Furthermore, to allow the PUT to undergo a battery electric power test through a battery simulation unit, the present invention discloses that the control unit can switch between the battery simulation unit and the power-storing unit to select between performing a battery electric power test on the PUT with an electric power supplied by the battery simulation unit, and allowing the power-storing unit to supply power to the PUT or receive a charging voltage from the PUT. The PUT is unable to operate while the control module is switching between the power-storing unit and the battery simulation unit, and this problem is solved by a power-hoarding unit having a compensated power stored therein beforehand.

### BRIEF DESCRIPTION

Objectives, features, and advantages of the present invention are hereunder illustrated with specific embodiments in conjunction with the accompanying drawings, in which:

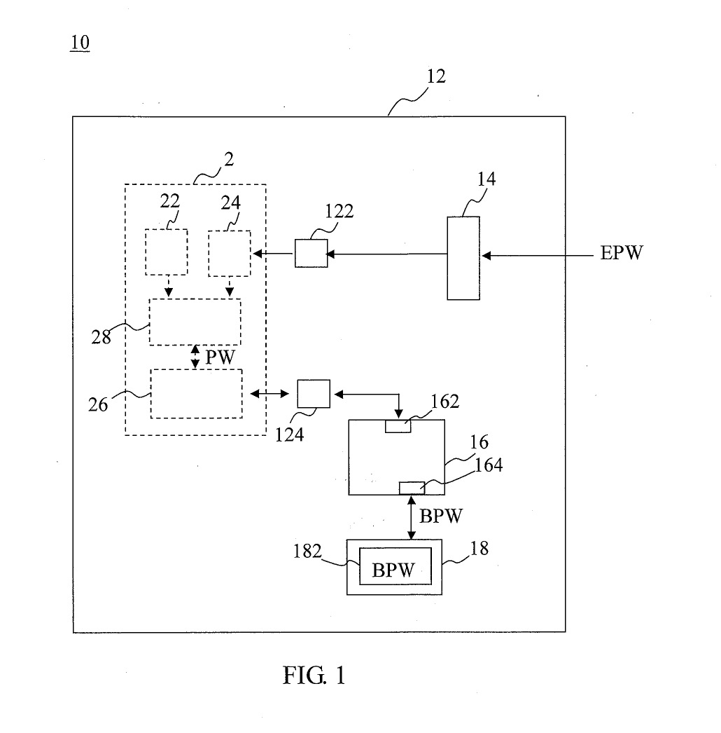

FIG. 1 is a block schematic view of a test device with uninterruptible power supply according to the first embodiment of the present invention;

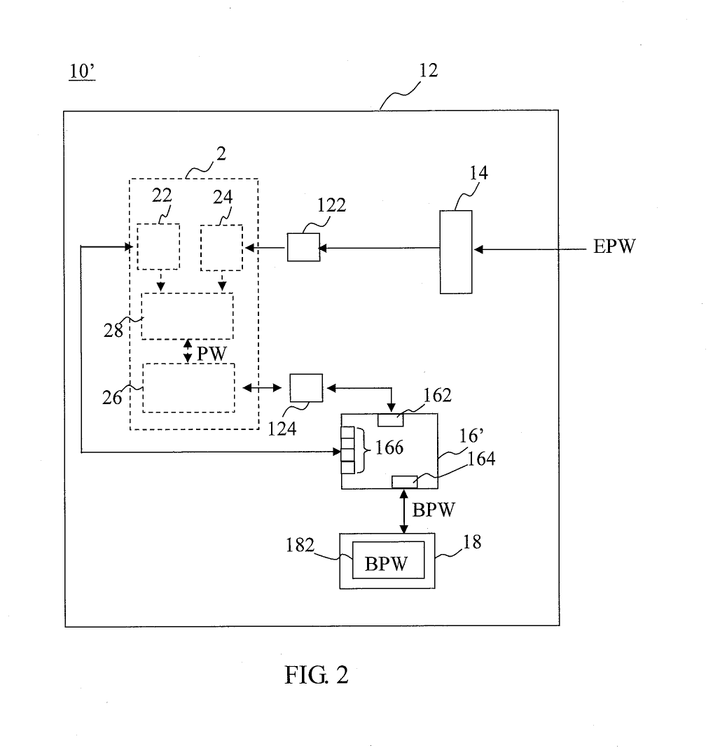

FIG. 2 is a block schematic view of a test device with uninterruptible power supply according to the second embodiment of the present invention;

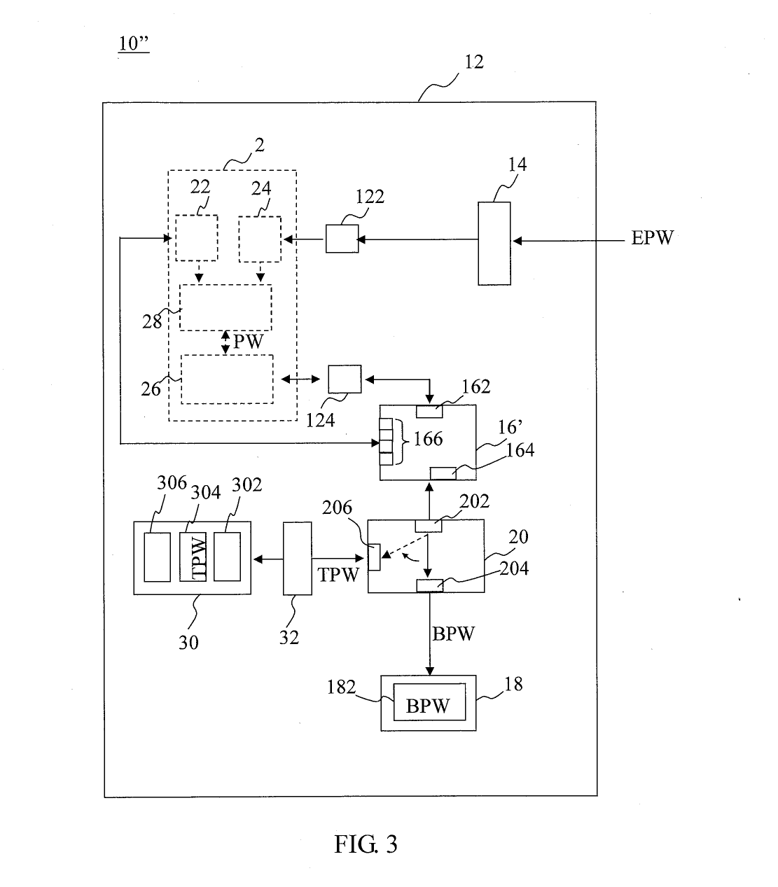

FIG. 3 is a block schematic view of a test device with uninterruptible power supply according to the third embodiment of the present invention; and

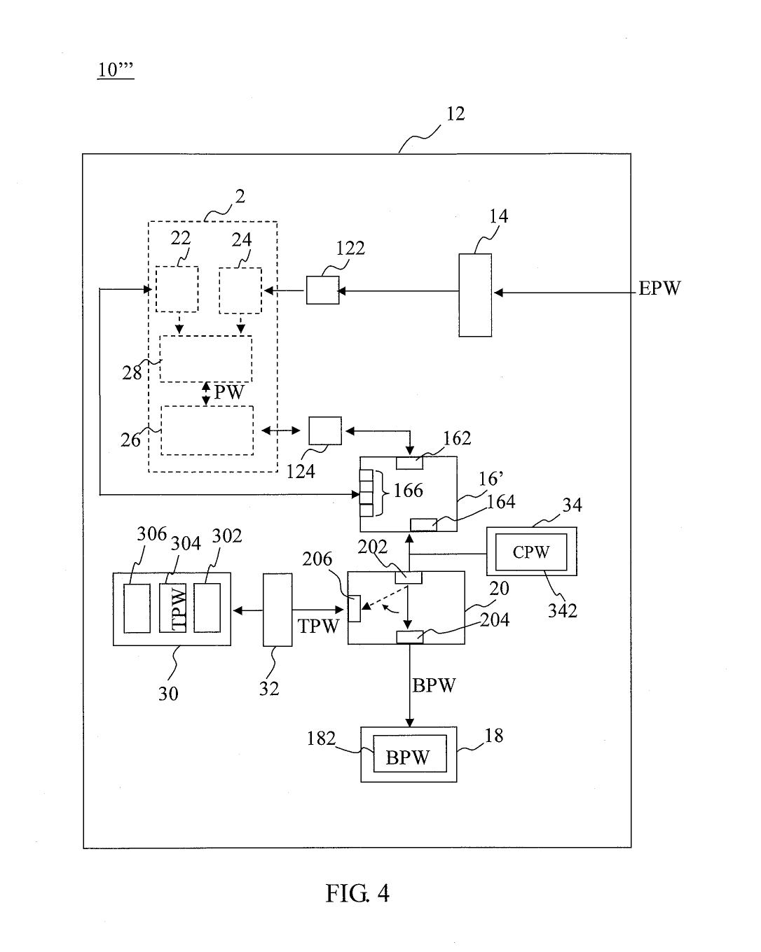

FIG. 4 is a block schematic view of a test device with uninterruptible power supply according to the fourth embodiment of the present invention.

### DETAILED DESCRIPTION

Referring to FIG. 1, there is shown a block schematic view of a test device 10 with uninterruptible power supply according to the first embodiment of the present invention. As shown in FIG. 1, the test device 10 with uninterruptible power supply supplies an external power EPW to a product under test (PUT) 2 for performing an electric power test thereon. The PUT 2 comprises a processing unit 22, a power input end 24, a battery connection end 26, and a charging and discharging circuit 28. The charging and discharging circuit 28 receives the external power EPW via the power input end 24. The charging and discharging circuit 28 is connected to the battery connection end 26. The processing unit 22 controls how the charging and discharging circuit 28 performs charging and discharging at the battery connection end 26. The charging and discharging circuit 28 converts the external power EPW into a power PW required for the operation of the PUT 2. For example, the external power EPW is an alternating current (AC) power or a direct current (DC) power. For example, the external power EPW is generated by AC-to-DC conversion or generated by DC-to-DC conversion.

The test device 10 with uninterruptible power supply comprises a test platform 12, a first electrical connection unit 14, a second electrical connection unit 16, and a power-storing unit 18. The test platform 12 is capable of carrying the PUT 2. The test platform 12 has a first test port 122 and a second test port 124. Positioning the PUT 2 on the test platform 12 connects the first test port 122 to the power input end 24 and connects the second test port 124 to the battery connection end 26. That is to say, the PUT 2 is electrically connected to the test platform 12 via the first test port 122 and the second test port 124 for performing a related electrical test thereon.

The first electrical connection unit 14 connects with the first test port 122 and receives the external power EPW. That is to say, the first electrical connection unit 14 receives the external power EPW and transmits the external power EPW to the first test port 122. Then, the first test port 122 transmits the external power EPW to the charging and discharging circuit 28 of the PUT 2. Eventually, the charging and discharging circuit 28 converts the received external power EPW into the power PW required for the operation of the PUT 2. In this regard, when supplied with the external power EPW, the PUT 2 maintains its operation and is ready for subsequent related tests.

The second electrical connection unit 16 has a first charging and discharging connection end 162 and a second charging and discharging connection end 164. The first charging and discharging connection end 162 is connected to the battery connection end 26 via the second test port 124. The second electrical connection unit 16 supplies another power PW to the PUT 2. For example, the second electrical connection unit 16 supplies a DC power to the PUT 2 via the battery connection end 26 for simulating supplying the power PW from the PUT 2 in a battery mode. Besides, the power PW originates from the test device 10 with uninterruptible power supply instead of the PUT 2.

The power-storing unit 18 has a power-storing space 182 stored therein with a battery power BPW, and is exemplified by a secondary battery having a battery cell. The power-storing unit 18 is connected to the second test port 124 via the second charging and discharging connection end 164, such that two-way charging and discharging take place between the power-storing unit 18 and the PUT 2. The battery power BPW supplies power to the battery connection end 26. The power-storing space 182 receives a charging voltage generated by the charging and discharging circuit 28.

In an embodiment, the external power EPW is transmitted to the charging and discharging circuit 28 via the first electrical connection unit 14 and the first test port 122. Then, the external power EPW or the power PW converted therefrom, is transmitted from the charging and discharging circuit 28 to the power-storing unit 18 via the second test port 124 so as to charge the power-storing unit 18 and form the battery power BPW therein. The processing unit 22 of the PUT 2 controls the charging and discharging behavior taking place between the charging and discharging circuit 28 and the power-storing unit 18.

Hence, as disclosed in the present invention, the test device 10 with uninterruptible power supply operates in several embodiments with respect to power usage. In the first embodiment, the charging and discharging circuit 28 simply receives the external power EPW through the first test port 122 and the first electrical connection unit 14 and supplies the external power EPW to the PUT 2 for the operation thereof. In the second embodiment, not only is a power supplied to the PUT 2 for the operation thereof, but the second test port 124 and the second electrical connection unit 16 charge the power-storing unit 18 to generate the battery power BPW. In the third embodiment, if the charging and discharging circuit 28 is unable to receive the external power EPW, the charging and discharging circuit 28 will receive the battery power BPW from the power-storing unit 18 and supply the battery power BPW to the PUT 2 for the operation thereof.

Referring to FIG. 2, there is shown a block schematic view of a test device 10′ with uninterruptible power supply according to the second embodiment of the present invention. As shown in FIG. 2, the test device 10′ with uninterruptible power supply comprises the test platform 12, the first electrical connection unit 14, and the power-storing unit 18 as the test device 10 in the first embodiment does, but the test device 10′ in the second embodiment is different from the test device 10 in the first embodiment in that the test device 10′ in the second embodiment comprises a second electrical connection unit 16′. The second electrical connection unit 16′ further comprises a status detection end 166 connected to the power-storing unit 18 and the processing unit 22 for enabling the processing unit 22 to detect the status of the battery power BPW stored in the power-storing space 182. For example, in the situation where the status detection end 166 serves to perform battery protection detection, battery power level detection, and/or battery temperature detection, and/or serves as a grounding end, the processing unit 22 is capable of identifying the charging and discharging status of the power-storing space 182 of the power-storing unit 18.

Referring to FIG. 3, there is shown a block schematic view of a test device 10″ with uninterruptible power supply according to the third embodiment of the present invention. As shown in FIG. 3, in addition to the test platform 12, the first electrical connection unit 14, the second electrical connection unit 16′, and the power-storing unit 18 in the second embodiment, the test device 10″ with uninterruptible power supply in the third embodiment further comprises a control module 20.

The control module 20 has a first connection port 202, a second connection port 204, and a third connection port 206. The control unit 20 is disposed between the second charging and discharging connection end 164 and the power-storing unit 18. The first connection port 202 is switchable between the second connection port 204 and the third connection port 206. The second connection port 204 is connected to the power-storing unit 18. In an embodiment, the control module 20 is a relay.

Furthermore, the test device 10″ with uninterruptible power supply further comprises a battery simulation unit 30. The battery simulation unit 30 has a test voltage output end 302, a virtual test battery 304, and a voltage detection end 306. The test voltage output end 302 is connected to the third connection port 206. The virtual test battery 304 generates and transmits a test power TPW to the test voltage output end 302. The voltage detection end 306 detects the state of use of the virtual test battery 304, such as the degree of power loss or the stability of power consumption.

Under the control of the control unit 20, the first connection port 202 switches to the third connection port 206, and the first connection port 202 is electrically connected to the third connection port 206, such that the test power TPW is supplied to the battery connection end 26 via the control unit 20 and the second electrical connection unit 16′.

In another embodiment, the test device 10″ with uninterruptible power supply further comprises a switching circuit 32. The switching circuit 32 is disposed between the battery simulation unit 30 and the control module 20 for controlling the output of the test power TPW. In this regard, under the control of the switching circuit 32, it is feasible to accurately determine whether to output the test power TPW.

Referring to FIG. 4, there is shown a block schematic view of a test device 10′″ with uninterruptible power supply according to the fourth embodiment of the present invention. As shown in FIG. 4, in addition to the test platform 12, the first electrical connection unit 14, the second electrical connection unit 16′, the power-storing unit 18, the battery simulation unit 30, and the switching circuit 32 in the third embodiment, the test device 10′″ with uninterruptible power supply in the fourth embodiment further comprises a power-hoarding unit 34. The power-hoarding unit 34 has a power-hoarding space 342 stored therein with a compensated power CPW. The power-hoarding unit 34 is disposed between the second electrical connection unit 16′ and the control unit 20. The power-hoarding unit 34 compensates for one of the failure of the second electrical connection unit 16′ to receive the test power TPW and the failure of the second electrical connection unit 16′ to receive the battery power BPW as a result of the switching of the first connection port 202 between the second connection port 204 and the third connection port 206 in the control module 20 (that is, the scenario where the first connection port 202 switches to the second connection port 204, and the scenario where the first connection port 202 switches to the third connection port 206.) In other words, if the first connection port 202 is connected to neither the second connection port 204 nor the third connection port 206, the first connection port 202 cannot receive any power required for the PUT 2.

Furthermore, once the first connection port 202 is connected to the third connection port 206, the battery simulation unit 30 will charge the power-hoarding unit 34. Once the first connection port 202 is connected to the second connection port 204, the power-storing unit 18 will charge the power-hoarding unit 34. Hence, the power-hoarding unit 34 is stored with the compensated power CPW for coping with the power supply suspension that accompanies a switching process, regardless of the switching mode.

As disclosed in the present invention, a test device with uninterruptible power supply not only enables the PUT to receive the external power EPW required for the operation of the PUT, but also enables the PUT to selectively allow the power-storing unit built in the test device with uninterruptible power supply to supply the power required for the operation of the PUT. Hence, the present invention ensures that the PUT can maintain its operation while being switched between testing production lines and receiving no external power EPW which should otherwise be supplied to the PUT, such that the PUT can be freely switched between the testing production lines without restarting.

Furthermore, the present invention dispenses with the hassles of providing an additional charging and discharging circuit for charging the power-storing unit, but enables the power-storing unit to be directly charged by the charging and discharging circuit built in the PUT.

Furthermore, to enable a battery simulation unit to perform a battery electric power test on the PUT, a control unit switches between the battery simulation unit and the power-storing unit for selectively driving the battery simulation unit to supply power required for performing the battery electric power test on the PUT, or driving the power-storing unit to supply power to the PUT or receive a charging voltage from the PUT. In addition, a power-hoarding unit is stored with a compensated power for preventing the failure of the PUT to operate as a result of power supply suspension that accompanies the switching of the control module between the power-storing unit and the battery simulation unit.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A test device with uninterruptible power supply supplying an external power to a product under test (PUT), the PUT comprising a processing unit, a power input end, a battery connection end, and a charging and discharging circuit, the charging and discharging circuit receiving the external power via the power input end, being connected to the battery connection end, and being controlled by the processing unit, the test device comprising:
a test platform having a first test port connected to the power input end and a second test port connected to the battery connection end;
a first electrical connection unit connected to the first test port and receiving the external power, the external power being transmitted to the PUT via the first test port;
a second electrical connection unit having a first charging and discharging connection end and a second charging and discharging connection end, the first charging and discharging connection end being connected to the battery connection end via the second test port; and
a power-storing unit having a power-storing space stored therein with a battery power, connected to the second test port via the second charging and discharging connection end, and performing two-way charging and discharging, the battery power being supplied to the battery connection end, and the power-storing space receiving a charging voltage generated by the charging and discharging circuit.

2. The test device of claim 1, wherein the second electrical connection unit further comprises a status detection end connected to the power-storing unit and the processing unit for enabling the processing unit to detect a status of the battery power in the power-storing space.

3. The test device of claim 2, wherein the status detection end serves a function of at least one of battery protection detection, battery power level detection, battery temperature detection, and a grounding end.

4. The test device of claim 1, further comprising a control unit having a first connection port, a second connection port, and a third connection port and disposed between the second charging and discharging connection end and the power-storing unit, the first connection port being switchable between the second connection port and the third connection port, and the second connection port being connected to the power-storing unit.

5. The test device of claim 4, further comprising a battery simulation unit having a test voltage output end, a virtual test battery, and a voltage detection end, the test voltage output end being connected to the third connection port, the virtual test battery generating and transmitting a test power to the test voltage output end, and the voltage detection end detecting a state of use of the virtual test battery.

6. The test device of claim 5, wherein, under control of the control unit, the first connection port switches to the third connection port, and the test power is supplied to the battery connection end via the control unit and the second electrical connection unit.

7. The test device of claim 6, further comprising a power-hoarding unit having a power-hoarding space stored therein with a compensated power and disposed between the second electrical connection unit and the control unit for compensating for one of a failure of the second electrical connection unit to receive the test power and a failure of the second electrical connection unit to receive the battery power as a result of the switching of the first connection port between the second connection port and the third connection port in the control module.

8. The test device of claim 7, wherein, once the first connection port is connected to the third connection port, the battery simulation unit will charge the power-hoarding unit.

9. The test device of claim 7, wherein, once the first connection port is connected to the second connection port, the power-storing unit will charge the power-hoarding unit.

10. The test device of claim 4, wherein the control module is a relay.

11. The test device of claim 5, further comprising a switching circuit disposed between the battery simulation unit and the control module for controlling an output of the test power.
